(19) United States
(12) Patent Application Publication
(10) Pub. No.: US 2010/0255412 A1
(43) Pub. Date: Oct. 7, 2010

(54) Photo-imaging Hardmask with Negative Tone for Microphotolithography

(76) Inventor: Sam Xunyun Sun, Columbia, MO (US)

Correspondence Address: Sam Sun, 4500 Reedsport Ct., Columbia, MO, 65203, US

(21) Appl. No.: 12/754,402

(22) Filed: Apr. 5, 2010

Related U.S. Application Data
(60) Provisional application No. 61/166,991, filed on Apr. 6, 2009.

(51) Int. Cl. G03F 1/00; G03F 7/004; G03F 7/20

(52) U.S. Cl. 430/5; 430/270.1; 430/319

(57) ABSTRACT

Disclosed is a method of making polysiloxane and polysilsesquioxane hardmask layer photo-imageable with a negative tone. The method is based on a photosensitizer and film modifier. The film modifier reduces pore size of the hardmask films for diffusion control. The negative-tone photo-imageable hardmask is especially beneficial for forming trenches and vias on exposure tools of extreme UV and deep UV lithography. Compositions of negative-tone photo-imageable hardmask based on the chemistry of polysiloxane and polysilsesquioxanes are disclosed as well. Further disclosed are processes of using photo-imageable hardmasks to create isolated trenches or vias on semiconductor substrates with or without an intermediate layer.

### CROSS-REFERENCE TO RELATED APPLICATIONS

This application claims the priority benefit of a provisional application entitled SELF-IMAGING HARD MASK WITH NEGATIVE TONE FOR PHOTOLITHOGRAPHY with application No. 61/166,991 filed Apr. 6, 2009 incorporated by reference herein.

### BACKGROUND OF THE INVENTION

1. Field of the Invention

The present invention relates in general to the process of microphotolithography in which a photosensitive layer and an anti-reflective coating are involved for forming structural patterns on semiconductor substrates.

2. Description of Prior Art

It has long been known that high-energy radiations can cause condensation reactions to polysiloxane or polysilsesquioxane films, especially with presence of photosensitive catalysts such as photoacid generators. This photochemical property of polysiloxanes and polysilsesquioxanes has been investigated for applications in microphotolithographic processes. There are two primary driving forces for those investigations. One is to make the coatings permanent insulating layers in microelectronic devices. Another is to make the coatings sacrificial films for delineating.

Search for published prior art revealed that most invention disclosures on permanent insulating layers were filed by device manufacturers (For example, U.S. Pat. No. 7,297,464 and U.S. Pat. No. 7,323,292). Those inventors intuitively understood the value and potential of such insulating materials. First, polysiloxane or polysilsesquioxane films can be thermally converted to common SiO2 dielectric layers. Second, photo-imageability of the insulating layers greatly simplifies the process. Inventors suggested that the photosensitive polysiloxane or polysilsesquiocane films require only steps of lithographic patterning, and thermal conversion to create dielectric layers with desired patterns, such as trenches or vias. Conventional process, on the other hand, requires steps of depositing or growing SiO2, forming an antireflective coating (ARC), and coating a photoresist. Trenches or vias are first formed on photoresist, and then etched into the insulating layer. Obviously, the conventional process is much more complicated and costly.

In reality, however, converting polysiloxane or polysilsesquioxane coatings into dielectric layers with trenches and vias is extremely difficult, if not impossible. First, the photochemistry of polysiloxanes and polysilsesquioxanes is vey elusive as platform of photo-imaging for precisely defined patterns. For example, solubility contrast of the films produced by radiations has to be extraordinarily high. Any film loss at edges will make the trenches and vias useless. Second, delineating resolution of polysiloxanes and polysilsesquioxanes films is far from the criteria of patterning, due to high diffusion of catalysts in the porous coatings. Even the most advanced hydrocarbon-based photoresist can not meet the criteria on film integrity, sidewall angle, pattern edge roughness, and resolving capability for permanent trenches and vias on the dielectric layers. Third, reflectivity control in the lithographic process is impossible, due to the limitations of what can be deposited under the dielectric layers as permanent elements of the devices. It is common knowledge in the field of invention that fine patterns such as trenches and vias can not be created by lithography without precise control of reflected radiations from substrates.

Those realistic difficulties made material venders, such as photoresist suppliers, less enthusiastic about the idea of using polysiloxane or polysilsesquioxane coatings for photo-imageable insulating layers. That is why the enthusiasm from end users has not been materialized.

The idea of making photoresist out of polysiloxane or polysilsesquioxane coatings is not more plausible. Search for prior art revealed that the majority patents attempted to make photoresist out of the polysiloxane and polysilsesquioxne chemisty with a positive tone, not with the straightforward negative tone (For example, U.S. Pat. No. 7,510,816 B2, U.S. Pat. No. 6,632,582 B2, U.S. Pat. No. 4,481,049 and U.S. Pat. No. 6,974,655). Positive-tone photoresist requires hydrocarbon functional groups on the “—Si—O—” chains for the de-protection mechanism to work. In contrast, negative-tone photoresist of polysiloxanes or polysilsesquioxanes requires only the simple photosensitized crosslinking reactions.

There are reasons for more publications on positive-tone than that on negative-tone polysiloxane and polysilsesquioxane photoresist. First, it is widely believed in the field of invention that positive-tone photoresist intrinsically has more resolving power than negative-tone photoresist. Therefore, research on negative-tone photoresist is largely neglected. Second, positive-tone photoresist is overwhelmingly used in the industry. Implementation of polysiloxane or polysilsesquioxane photoresist is easier with positive tone than with negative tone. Therefore, more research was conducted on the positive-tone chemistry. Third, the positive-tone chemistry with de-protection mechanisms is rather complicated. A variety of functional groups and labile protective groups are available for selection. Complicated chemistry requires complicated research, and therefore, ample publications are produced.

Despite all the research effort, polysiloxane- or polysilsesquioxane-based photoresist with positive tone has never prevailed, primarily due to diluted silicon content, lack of robustness, and incompetent resolution. The present invention is not part of the losing battle on positive-tone photoresist of polysiloxane or polysilsesquioxane. Disclosed are mechanisms, compositions and applications of photo-imageable polysiloxane- and polysilsesquioxane-based hardmask with negative tone.

The notion that positive-tone photoresist has more resolving power than negative-tone photoresist can be understood from three aspects. (1) There has never been a negative-tone chemistry platform as successful as the ones that C. Grant Willson, Jean Frechet and Hiroshi Ito discovered for positive photoresist in the early 1980s. Authentic comparative test is unable to conduct. Therefore, the conclusion on resolution advantage of positive-tone photoresist is more mysterious than scientific. (2) Negative-tone chemistry is based on crosslinking. Organic solvents are normally used to dissolve un-crosslinked films. The welling nature of crosslinked hydrocarbon films in solvent developers limits, more or less, the resolving capabilities. (3) For positive-tone photoresist, resolution can be enhanced by over exposure to radiations. Isolated lines, for example, become finer as exposure dose increases. For negative-tone photoresist, while high dose increases pattern dimensions, low dose increases risk of pattern lift. In other words, resolution of negative-tone photoresist can not be improved by manipulating the exposure dose. Due to those disadvantages and difficulties, development work on negative-tone photoresist has essentially been neglected for a long time.

The present invention establishes a chemistry platform that enhances resolution of negative-tone hardmask to the level of positive-tone photoresist. The disclosed chemistry, mechanism, and compositions of the photo-imageable hardmask resolve problems of film swelling and catalyst diffusion. The negative-tone photo-imageable hardmask is designed for extreme UV (e.g. at wavelength of 13.5 nm) and deep UV (e.g. at wavelength of 193 nm) dark-field lithography. Dark-field lithography is typically used for creating trenches and vias.

At wavelengths of extreme UV radiations, existing photoresists are highly absorptive. Transparent films to radiations with so high energy do not exist. Radiation absorption is counter-productive to positive-tone delineating mechanism. Take line/space patterns as an example. At low radiation dose, exposed spaces may scum. At high radiation dose, unexposed lines may taper. Radiation absorption, on the other hand, has less impact on negative-tone delineating mechanism. High or low, radiation dose has no effect on unexposed spaces. In other words, dissolution rate of negative-tone photoresist films in unexposed regions does not depend on radiations. When exposure takes place, radiation starts from top of films. Upper part of the exposed films may crosslink more than lower part due to radiation absorption. When the films are developed, developers work from the top as well. Therefore, the crosslink gradient and development gradient cancel each other to some degree. This phenomenon can be exploited to the maximum by fine tuning dissolution rate of unexposed films.

At wavelengths of deep UV radiations, film transparency is not a problem. However, positive-tone photoresist has experienced great difficulties in dark-field lithography. When radiation dose is high enough to clear the exposed areas such as trenches or vias, dimensions of the areas are usually expanded. Such expansion is least desired for microelectronic devices. Negative-tone mechanism, on the other hand, converts dark-field exposure to bright-field exposure for trenches and vias. Negative-tone photoresist and bright-field exposure work together constructively. First, vias or trenches that are not exposed are easy to clear out regardless radiation dose. Second, dimensions of vias and trenches favorably shrink with increased exposure dose.

Reports on silsesquioxane as e-beam photoresist are available (For example, Microelectronic Engineering, Volumes 61-61, July 2002, Pages 803-809). It is based on an extremely simple mechanism, i.e. the high-energy radiations cause crosslinking condensation reactions to the film. The e-beam photoresist obviously has a negative tone. The exposure energy is not chemically magnified since there is no photosensitizer. Absence of photosensitizer and lack of photosensitizer diffusion promises robust and high-resolution photoresist.

Reports on more complicated sensitized photoresist are less common (For example, U.S. Pat. No. 5,554,465). Research is discouraged by problems described earlier, for example, lack of enthusiasm on negative-tone photoresist, catalyst diffusion, film swelling, and myth on low resolution. A few overly simplified protocols can be found from prior arts. Disclosed compositions of those protocols are primarily consisted of two components, i.e. polysiloxane or polysilsesquioxane resin plus photoacid generator. Ordinarily skilled in the field of invention understands that two-component photoresist, without a quencher, can never work for advanced high-resolution lithography. Research of the present invention further revealed that, without film modification, catalysts diffuse readily in polysiloxane or polysilsesquioxane films even at ambient temperature. Diffusion with such severity determines that the reported simple protocols are not feasible for high-resolution lithography. Indeed, commercial photoresist products based on those protocols have not been available. Any inventions that do not disclose methods of controlling catalyst diffusion have little meaning to high-resolution lithography. The present invention discloses all the necessary mechanisms, methods, and components to make polysiloxane and polysilsesquioxane hardmasks photo-imageable with high delineating resolution. The invented photo-imageable hardmasks, with a negative tone, are especially suitable for extreme UV and deep UV lithography for creating trenches and vias.

### SUMMARY OF THE INVENTION

This summary provides a simplified description of the invention as a basic overview, and does not provide detailed processes and all the critical elements of the invention. This brief overview should not be used to constrain the full scope of the invention.

Photo-imageable hardmask (PIHM) of the present invention has a negative response to UV radiations, i.e. radiations make films insoluble in organic solvents or alkaline aqueous solutions. Photochemical reactions of the present invention are sensitized by photoacid generator. Initial films of the photo-imageable hardmask are readily soluble or dispersible in organic solvents or alkaline aqueous solutions. If the films are adequately radiated, the photo-generated acid accelerates condensation reactions to form molecular networks of the resin. The catalyzed condensation reactions may take place at ambient or higher temperatures. The molecular networks prevent the films from dissolving or dispersing in organic solvents or alkaline aqueous solutions.

The hardmask films are modified for diffusion control. Film modifiers are used to constrain diffusion pathways of photoacid generators, quenchers, or any other small molecules.

Resins in compositions of the negative-tone photo-imageable hardmask of the present invention are consisted of polysiloxanes and polysilsesquioxanes that are prepared from monomers with molecular formulas of (A), (B) and (C).

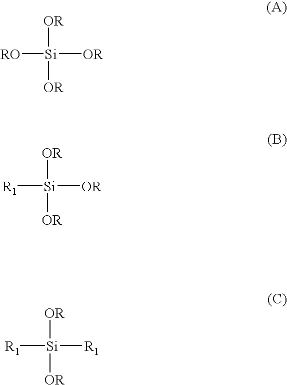

In formulas (A), (B) and (C), R is selected from the groups consisting of hydrogen and C₁-C₄ alkyls, and R₁ is selected from the groups consisting of alkyl, aryl, alkene, alicyclic groups, epoxy-alkyl, and epoxy-cycloalkyl.

Out of the monomers, the derived siloxane and silsesquioxane polymers are consisted of linear structures (D) and network structures (E).

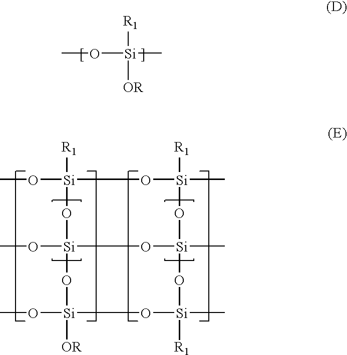

In molecular structures (D) and (E), R is selected from the groups consisting of hydrogen and C₁-C₄ alkyls, and R₁ is selected from the groups consisting of alkyl, aryl, alkene, alicyclic, epoxy-alkyl, and epoxy-cycloalkyl. Molar ratio of OR to R₁ in structure (E) is less than 0.2 in the final polymers.

Structures (D) and (E) are simplified expressions to depict the polymer molecules. Due to the complexity and diversity of molecular structures of polysiloxanes and polylilsesquioxanes, those simplified expressions should not be taken as exact templates to confine selections of the resin polymers. The polymers should be defined by structures (D) and (E) together with information of monomers and polymerization process.

The polymers are responsible for forming films and resisting plasma etch. Besides resin polymers, other essential constituents of compositions of negative-tone photo-imageable hardmask include film-modifier, photoacid generator, quencher, and solvents. Solid chemicals constitute 1%-10% of the compositions. Dry film thickness of photo-imageable hardmasks ranges from 20 to 100 nanometers. Content of elemental silicon in dry films is from 30% to 41% by weight, and more commonly from 35% to 40% by weight.

The photo-imageable hardmask with such high silicon is capable of forming precursor patterns on semiconductor substrates with or without an intermediate layer. Intermediate layer is a coating of hydrocarbon polymers, multiple times thicker than the photo-imageable hardmask. Intermediate layer serves as a mask to the substrates when etched by plasma. It functions as an antireflective coating as well. If intermediate layer is not used, a thin antireflective coating is necessary to control reflection of radiations from substrates. Antireflective coatings have no function of masking plasmas.

In one embodiment, negative-tone photo-imageable hardmask was used in conjunction with an intermediate layer to create isolated trenches and vias on semiconductor substrates for fabricating integrated circuit. The intermediate layer was formed by spin-coating a composition on a polysilicon substrate. The intermediate layer had a thickness of 300 nanometers after being cured on a hot surface. A film of photo-imageable hardmask was formed on top of the intermediate layer by spin-coating a composition. The film was dried by a post-application bake. The dried film had a thickness of 56±5 nanometers. The photo-imageable hardmask was exposed to radiations with a wavelength of 193 nanometers through a photomask. A post-exposure bake was followed. The photo-imageable hardmask was then developed in a tetramethylammonium hydroxide aqueous solution. The unradiated regions of the film dissolved, and images formed. The images were etched to the intermediate layer by oxygen-containing plasma. The images on the intermediate layer were then etched to the polysilicon substrate by chlorine-containing plasma.

In another embodiment, negative-tone photo-imageable hardmask was used in conjunction with a thin antireflective coating to create isolated trenches and vias on semiconductor substrates for fabricating integrated circuit. The antireflective coating of 32 nanometers was formed by spin-coating and thermally curing a composition on a polysilicon substrate. A film of photo-imageable hardmask was formed on top of the thin antireflective coating by spin-applying a composition. The film was dried by a post-application bake. The dried film had a thickness of 56±5 nanometers. The photo-imageable hardmask was exposed to radiations with a wavelength of 193 nanometers through a photomask. A post-exposure bake was followed. The photo-imageable hardmask was then developed in a tetramethylammonium hydroxide aqueous solution. The radiated regions of the film dissolved, and images formed. The images were etched to the polysilicon substrate by oxygen- and chlorine-containing plasma. The antireflective coating was etched through.

### BRIEF DESCRIPTION OF THE DRAWINGS

FIG. 1(A): Film stack of negative-tone photo-imageable hardmask process with an intermediate layer.

FIG. 1(B): Negative-tone photo-imageable hardmask being exposed to radiations with a photomask.

FIG. 1(C): Cross-section view of isolated trenches or vias formed on photo-imageable hardmask.

FIG. 1(D): Cross-section view of trenches or vias on intermediate layer formed by plasma etch.

FIG. 1(E): Cross-section view of trenches or vias on substrate formed by plasma etch.

FIG. 1(F): Cross-section view of trenches or vias on substrate after cleaning.

FIG. 2(A): Film stack for negative-tone photo-imageable hardmask process with a thin antireflective coating.

FIG. 2(B): Negative-tone photo-imageable hardmask being exposed to radiations with a photomask.

FIG. 2(C): Cross-section view of isolated trenches or vias formed on photo-imageable hardmask.

FIG. 2(D): Cross-section view of trenches or vias on substrate formed by plasma etch.

FIG. 2(E): Cross-section view of trenches or vias on substrate after cleaning.

### DETAILED DESCRIPTION OF THE PREFERRED EMBODIMENTS

Film-forming polymers in compositions of the negative-tone photo-imageable hardmask of the present invention are consisted of polysiloxanes and polysilsesquioxanes that are prepared from monomers with molecular formulas of (A), (B) and (C).

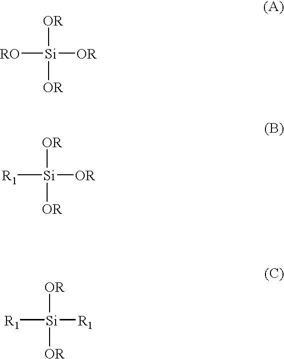

In formulas (A), (B) and (C), R is selected from the groups consisting of hydrogen and C₁-C₄ alkyls, and R₁ is selected from the groups consisting of alkyl, aryl, alkene, alicyclic, epoxy-alkyl, and epoxy-cycloalkyl.

Resin is formed by polymerizing monomers with molecular formulas of (A), (B) and (C). Multiple monomers with various R and R₁ groups are usually required to form each resin appropriate for photo-imageable hard mask. The polymerization is a condensation reaction under catalyzation. Acetic acid is one of the appropriate catalysts. Volatile alkanols are formed from the condensation reactions. The reactions take place in the medium of organic solvents. Propylene glycol methyl ether (PGME) and propylene glycol methyl ether acetate (PGMEA) are among preferred solvents. Reaction temperature is controlled preferably between 80° C. and 110° C., and more preferably between 90° C. and 100° C. The alkanols are distilled out the reactor as the reactions proceed. The distillate may include catalyst, water and solvents as well. A steady nitrogen stream flushes through the reactor to assist distillation. Polymerization is stopped when distillation is completed. Reaction time is typically from 2 to 8 hours. Weight-average molecular weight of the derived polysiloxane and polysilsesquioxane are preferably less than 50,000 grams per mole, and more preferably less than 10,000 grams per mole.

The polysiloxane and polysilsesquioxane resin is consisted of linear structures (D) and network structures (E).

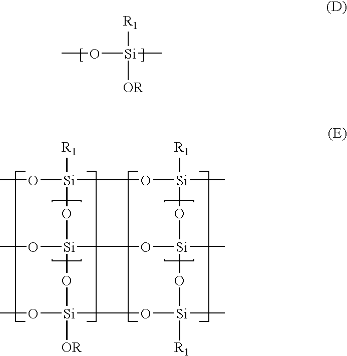

In molecular structures (D) and (E), R is selected from the groups consisting of hydrogen and C₁-C₄ alkyls, and R₁ is selected from the groups consisting of alkyl, aryl, alkene, alicyclic groups, epoxy-alkyl, and epoxy-cycloalkyl. Multiple hydroxyl groups are preferred on each molecular unit of the polymers.

Structures (D) and (E) are simplified expressions to depict the polymer molecules. Due to the complexity and diversity of molecular structures of polysiloxanes and polylilsesquioxanes, those simplified expressions should not be taken as exact templates to confine selections of the resin polymers. The polymers should be defined by structures (D) and (E) together with information of monomers and polymerization process.

Beside the polysiloxane and polysilsesquioxane resin, other essential constituents of the compositions include film-modifier, photoacid generator, quencher, and solvents.

The function of film-modifier is to control diffusion of photoacid generator and quencher in the film. Polysiloxane and polysilsesquioxane films are known porous media. Small molecules of photoacid generators and quenchers have high mobility in the films driven by diffusion force. In photoresist films, moderate diffusion is needed to achieve smooth and straight pattern sidewalls. Too much diffusion compromises profiles of photoacid generator distribution defined by exposure. Because of high diffusibility, films of polysiloxane and polysilsesquioxane have been considered not appropriate for delineating high-resolution images. Indeed, negative-tone photoresist of polysiloxane or polysilsesquioxane is yet to make its commercial debut, although the chemistry is quite intuitive. Film modification for diffusion control is vital aspect of the present invention to make silicon hardmasks photo-imageable with high resolution.

Diffusion control in prior art emphasized primarily on molecule dimensions of photoacid generators and post-exposure-bake temperatures. Neither method is applicable to polysiloxane and polysilsesquioxane resins. Inventors of the present invention observed significant diffusion of photoacid generator in polysiloxane or polysilsesquioxane films even at ambient temperatures. Film-modifier is based on the concept of constraining diffusion pathways of photoacid generators, quenchers, and other small-molecule components.

Film-modifiers are selected from polymers, oligomers, or non-polymeric compounds. Weight-average molecular weight of polymers or oligomers is preferably lower than 5,000 grams per mole, and more preferably lower than 2,000 grams per mole. Molecules of film-modifiers have to be small enough to fill in the film pores. Film-modifier may be a hydrocarbon compound, but preferably a silicon-containing compound. At least one hydroxyl group is attached to each molecule of film-modifiers. The hydroxyl groups participate condensation reactions of the film resin in the delineating process. Exemplary hydrocarbon film-modifiers include polyols such as 1,1,1-tris(hydroxymethyl)ethane and pentaerythritol. Exemplary silicon-based modifiers include silanols such as diphenylsilanediol. Film-modifier should not exceed 30%, and more preferably 10%, of the resin by weight. Concentrations of film-modifier in compositions are used to control diffusion length of photoacid generators, and quenchers. Multiple film-modifiers may be used in one composition.

Photoacid generators are compounds that release acid upon exposure to radiations with desired wavelengths. All known photoacid generators for compositions of de-protection photoresist are practically applicable to negative-tone photo-imageable hardmasks. Consideration shall be given to the diffusion aspect of photoacid generators in polysiloxane and plysilsesquioxane films. Suitable photoacid generators include onium salts such as sulfonium and iodinium salts. Sulfonium salts are compounds of sulfonium cations and sulfonates or methides. Exemplary sulfonium cations include triphenylsulfonium and tris(4-tert-butoxyphenyl)sulfonium. Exemplary sulfonates include trifluoromethanesulfonate and perfluoro-1-butanesulfonate. Exemplary methides include tris(trifluoromethyl)methide. Iodinium salts are compounds of iodonium cations and sulfonates. Exemplary iodinium cations are aryliodonium cations including diphenylodinium and bis(4-tert-butylphenyl)iodonium. Exemplary sulfonates include trifluoromethanesulfonate and perfluoro-1-butanesulfonate. Triphenylsulfonium tris(trifluoromethyl)methide is an especially important photoacid generator for compositions of the negative-tone photo-imageable hardmask. Molar ratio of photoacid generator to catalyst is preferably 0.5 to 1.5.

Quencher in compositions of the negative-tone photo-imageable hardmask has two functions. One is to control photospeed at reasonable levels by neutralizing unwanted photo-generated acid. Another is to counteract the diffusion of photoacid generators. A variety of amines are suitable quenchers for the negative-tone photo-imageable hardmask. Tested and proved quenchers include n-boc-piperidine, t-butyl 4-hydroxy-1-piperidinecarboxylate, triethanol amine, 1-piperidineethanol, and benzyltriethylammonium chloride. Molar ratio of quencher to photoacid generator is preferably from 0.2 to 10.

Suitable solvents for the compositions of negative-tone photo-imageable hardmask include, but are not limited to, propylene glycol methyl ether (PGME), propylene glycol methyl ether acetate (PGMEA), and ethyl lactate (EL).

The compositions of negative-tone hardmask are formulated by mixing the ingredients under agitation. When all the solid chemicals dissolved, the compositions are filtered through membranes with 0.02-micrometer pores. Solid content of the compositions of negative-tone photo-imageable hardmask is between 1% and 10%.

The compositions of negative-tone photo-imageable hardmask are applied on substrates preferably by spin-coating to form uniformed films. Spin speed can range from 1500 revolution per minute to 5000 revolution per minute. Spin-formed films of the negative-tone photo-imageable hardmask need to be dried on a hotplate surface of preferably 40° C.-120° C., and more preferably 60° C.-100° C., for preferably 30 seconds to 120 seconds, and more preferably 30 seconds to 60 seconds. The dried films of negative-tone photo-imageable hardmask are soluble in developers.

Elemental silicon constitutes 30%-41%, and more commonly 35%-40%, of dried films of photo-imageable hardmask by weight. As a reference, pure silicon dioxide is consisted of 46.7% silicon. The silicon-rich photo-imageable hardmask is highly resistant to attacks from oxygen, chlorine, and HBr plasmas.

Film thickness is adjustable by viscosity of the compositions, and speed of spin-coating. For processes of photolithographic patterning, film thickness may range from 10 nanometers to 100 nanometers, and more preferably from 40 nanometers to 100 nanometers. Refractive index (n) of the films is preferably from 1.4-1.9, and more preferably from 1.5-1.8. Extinction coefficient (k) of the films is preferably from 0.01 to 0.4.

The negative-tone photo-imageable hardmask is ready for radiation exposure immediately after post-application bake. Suitable radiation source for the exposure may have a wavelength that is commonly used in the field of invention, such as 365 nanometers, 248 nanometers, 193 nanometers, and 13.5 nanometers. In general, radiations with wavelengths shorter than 400 nanometers are preferred. A photomask with desired chrome patterns is placed between radiation source and surface of the photo-imageable hardmask. Image of the patterns is projected onto the hardmask surface. The image may not be visible to naked eyes, but radiation contrast with “bright” and “dark” regions are defined.

If the space between projection lens of the exposure tool and surface of the photo-imageable hardmask is filled with a fluid, known as immersion lithography in the field of invention, a top-coat may be needed. The top-coat may preserve the physicochemical properties of the photo-imageable hardmask surface, in addition to reduce risks of leaching from the hardmask.

Thermal treatment on a hotplate surface is necessary immediately after exposure. Appropriate bake temperatures are preferably 40° C.-120° C., and more preferably 60° C. -100° C., for preferably 30 seconds to 120 seconds, and more preferably 30 seconds to 60 seconds. The post-exposure bake (PEB) accelerates crosslinking reactions of the resin.

In dark regions of exposure, little acid is generated to catalyze condensation reactions. The film is not crosslinked. Like the initial film, unexposed films are soluble in organic solvents or alkaline aqueous solutions.

In bright regions of exposure, enough acid is generated to catalyze condensation reactions of the films. The condensation reactions may start at ambient temperature, but complete after the post-exposure bake. The condensation reactions create inter- and intra-molecule linkage bonds in the format of “—Si—O—”. Molecular networks are formed. The film in bright regions is therefore crosslinked and becomes insoluble in developers.

Suitable developers for the negative-tone photo-imageable hardmask may be organic solvents or alkaline aqueous solutions. The latter is more preferable. Preferred organic solvents include, but are not limited to, propylene glycol methyl ether (PGME), propylene glycol methyl ether acetate (PGMEA), ethyl lactate (EL), and cyclohexanone. Preferred alkaline developers may be water solutions of organic or inorganic bases, including tetramethylammonium hydroxide (TMAH), potassium hydroxide, and sodium hydroxide. The most preferable developer is aqueous solutions of tectramethylammonium hydroxide with concentrations ranging from 2.5 to 25 grams per liter.

Photo-imageable hardmask of the present invention is capable of forming precursor patterns on semiconductor substrates with or without an intermediate layer. Intermediate layer is a coating of organic polymers with a thickness between 100 nanometers and 500 nanometers. Intermediate layer functions as a mask to protect substrates from plasma etch. It serves as an antireflective coating as well. If intermediate layer is not needed, a thin antireflective coating is used to control reflection of radiations from substrates. Antireflective coating has a thickness between 20 nanometers and 80 nanometers. This thin layer is not an etch mask.

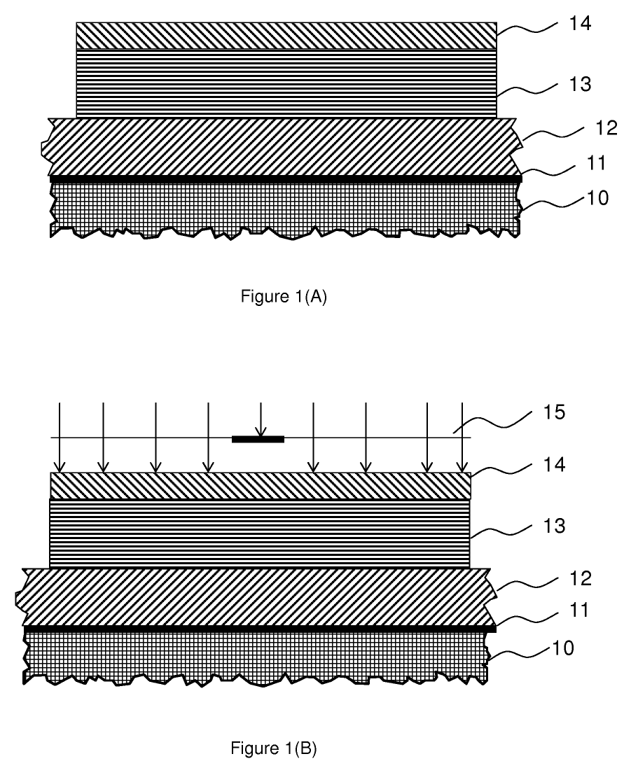

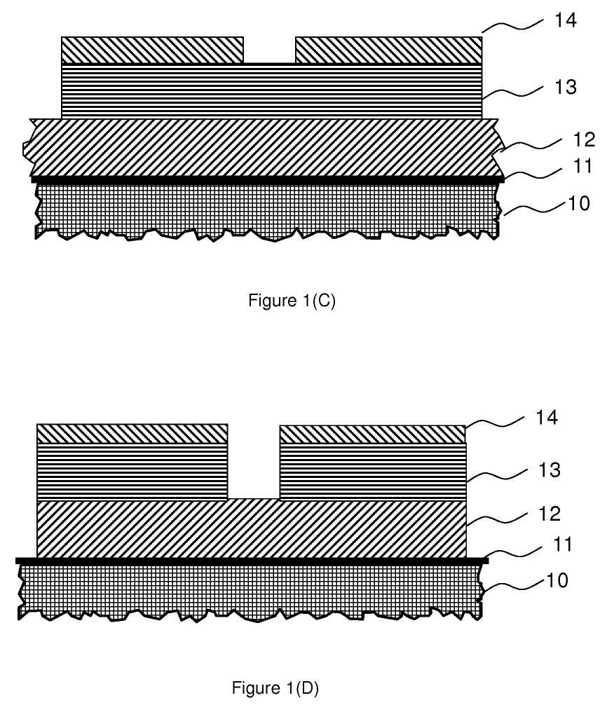

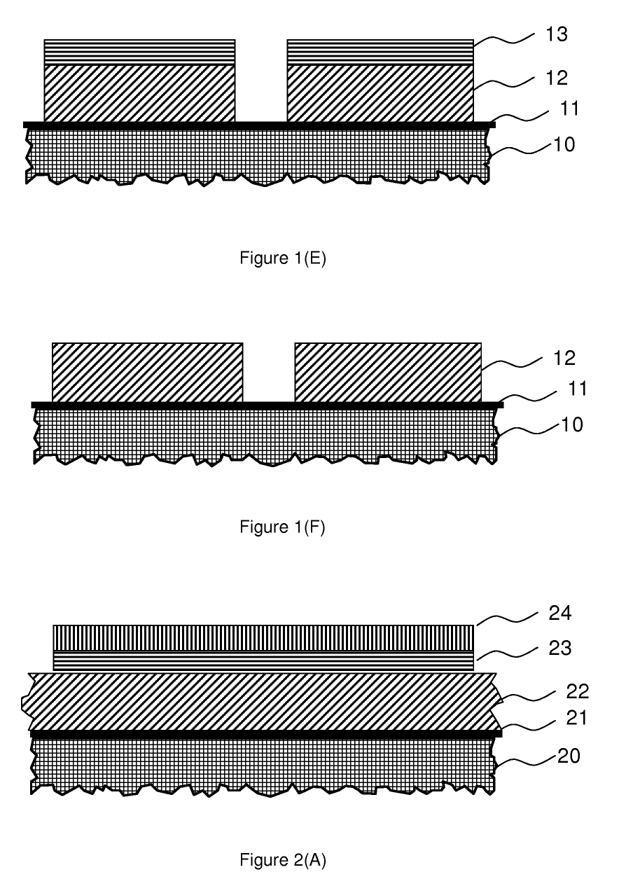

FIG. 1(A) shows film stack of one embodiment that the negative-tone photo-imageable hardmask was used in conjunction with an intermediate layer. The intermediate layer (13) was formed by spin-coating a composition on a polysilicon substrate (12) which was on an etch-stop layer (11). The carrier of the films is a silicon wafer (10). The substrate can be any of the common materials used in integrated circuitry (IC) fabrication, such as polysilicon, dielectrics, and metals. The substrate may have a flat or topographic surface. The intermediate layer (13) was cured on a hotplate surface of 200° C. for 60 seconds. Thickness of the intermediate layer (13) was 320±10 nanometers.

A composition of negative-tone photo-imageable hardmask was spin-coated on top of intermediate layer (13), and followed by a bake on a hotplate surface of 60° C. for 90 seconds. The photo-imageable hardmask (14) had a thickness of 56±5 nanometers.

FIG. 1(B) shows the negative-tone photo-imageable hard mask (14) being exposed to radiations with a photomask (15). Pattern images on the photomask (15) were projected on surface of the photo-imageable hardmask (14). The radiation had a wavelength of 193 nanometers.

The isolated chrome on the photomask (15) stops radiation from reaching the photo-imageable hardmask (14). Majority areas of the hardmask were exposed to radiation. It was a typical bright-field exposure. Since the hardmask had a negative tone, the bright-field exposure resulted in isolated trenches or vias. Note that the trenches and vias shrink as the exposure dose increases.

The exposure was followed by a bake on a hotplate surface of 100° C. for 90 seconds. The wafer was then submerged in an aqueous solution of tetramethylammonium hydroxide with a concentration of 4.7 grams per liter for development. Radiated portions of the photo-imageable hardmask dissolved in the developer. Isolated trenches or vias (in FIG. 1(C)) formed on the photo-imageable hardmask (14).

FIG. 1(D) shows the trenches or vias on photo-imageable hardmask (14) were transferred to the intermediate layer (13) by oxygen-containing plasma. Portions of the intermediate layer (13) that were subjected to plasma were removed. Portions of the intermediate layer (13) that were protected by the photo-imageable hard mask (14) were intact. Residual photo-imageable hard mask (14) was still visible.

FIG. 1(E) shows that the trenches or vias on intermediate layer (13) were transferred to the substrate (12) by chlorine-containing plasma. Portions of the substrate (12) that were subjected to plasma were removed. Portions of the substrate (12) that were protected by the intermediate layer (13) were intact. Residual intermediate layer (13) was still visible.

FIG. 1(F) shows the trenches or vias on substrate (12) after the residual intermediate layer was stripped off.

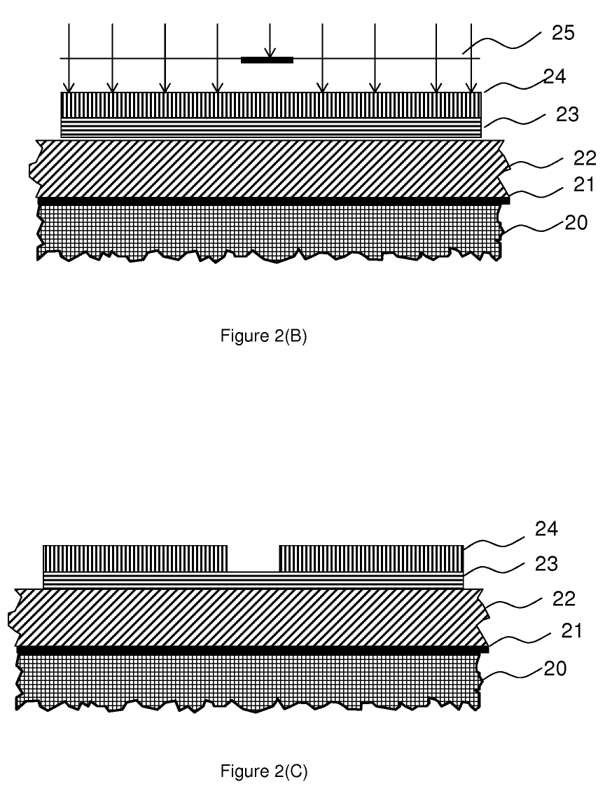

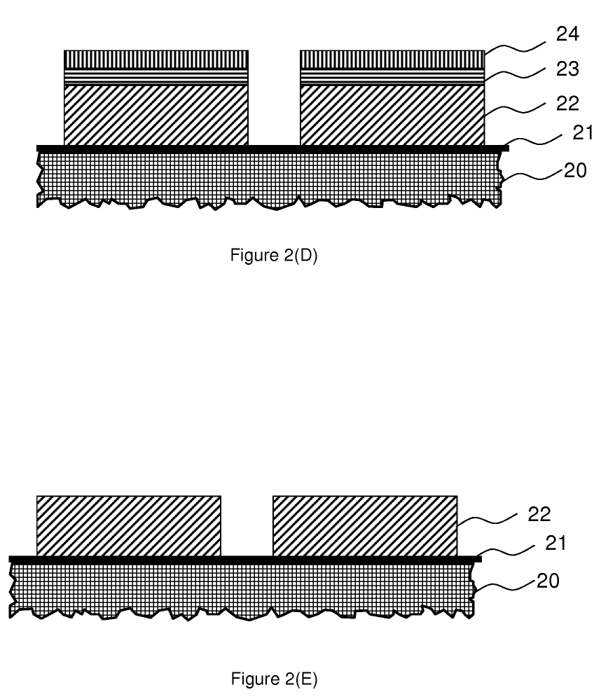

FIG. 2(A) shows film stack of another embodiment that the negative-tone photo-imageable hardmask was used in conjunction with a thin anti-reflective coating (ARC). The antireflective coating (23) was formed by spin-coating a composition on a polysilicon substrate (22) which was on an etch-stop layer (21). The carrier of the films was a silicon wafer (20). The substrate can be any of the common materials used in integrated circuitry (IC) fabrication, such as polysilicon, dielectrics, and metals. The substrate may have a flat or topographic surface. The antireflective coating was cured on a hotplate surface of 200° C. for 60 seconds. The antireflective coating (23) had a thickness of 32±2 nanometers that was optimal for reflectivity control. The thin antireflective coating (23) did not serve as an etch mask.

A composition of the negative-tone photo-imageable hardmask was spin-coated on top of the ARC layer (23), and followed by a bake on a hotplate surface of 60° C. for 90 seconds. The photo-imageable hardmask film (24) had a thickness of 56±5 nanometers.

FIG. 2(B) shows the negative-tone photo-imageable hard mask (24) being exposed to radiations with a photomask (25). Pattern images on the photomask (25) were projected on surface of the photo-imageable hardmask (24). The radiation had a wavelength of 193 nanometers.

The isolated chrome on the photomask (25) stops radiation from reaching the photo-imageable hardmask (24). Majority areas of the hardmask were exposed to radiation. It was a typical bright-field exposure. Since the hardmask had a negative tone, the bright-field exposure resulted in isolated trenches or vias. Note that the trenches and vias shrink as the exposure dose increases.

The exposure was followed by a bake on a hotplate surface of 100° C. for 90 seconds. The wafer was submerged in an aqueous solution of tetramethylammonium hydroxide with a concentration of 4.7 grams per liter for development. Radiated portions of the photo-imageable hardmask dissolved in the developer. Isolated trenches or vias (in FIG. 2(C)) formed on the photo-imageable hardmask (24).

FIG. 2(D) shows that the trenches or vias on photo-imageable hardmask (24) were transferred to the substrate (22) by oxygen- and chlorine-containing plasma. Portions of the antireflective coating (23) and substrate (22) that were subjected to plasma were removed. Portions of the antireflective coating (23) and substrate (22) that were protected by the photo-imageable hardmask (24) were intact. The antireflective coating (23) was punched through by plasma due to the thin thickness and fast etch rate. Residual photo-imageable hardmask (23) was still visible.

FIG. 2(E) shows the trenches or vias on substrate (22) after the residual photo-imageable hardmask and antireflective coating were stripped off.

### EXAMPLES

The following examples set forth preferred methods in accordance with the invention. It is to be understood, however, that these examples are provided by way of illustration and nothing therein should be taken as a limitation upon the overall scope of the invention.

### Example 1

### Synthesis of Polysiloxane and Polysilsesquioxane Resin I

TABLE 1
Monomers for Polysiloxane and Polysilsesquioxane Resin I:

| | |
|---|---|
| Methyl trimethoxy silane (Gelest, Morrisville, PA) | 65.2 grams |
| Tetraethoxy silane (Gelest, Morrisville, PA) | 26.6 grams |
| Phenyl trimethoxy silane (Gelest, Morrisville, PA) | 5.06 grams |
| 2-(3,4-Epoxycyclohexyl)ethyl trimethoxy silane | 1.57 grams |
| (Gelest, Morrisville, PA) | |

Monomers in Table 1, together with 80 grams of propylene glycol methyl ether acetate (from Sigma Aldrich (Milwaukee, Wis.)), were mixed in a 500-mL three-neck round-bottom flask. Attached to the flask were distillation condenser, thermometer, and nitrogen inlet. Nitrogen flow was set at 200 milliliters per minute. With stirring, temperature of the mixture in the flask was raised to 95° C. in oil bath. Then, 50 grams of 3-nomal acetic acid were slowly added to the flask. Condensation reactions began. Volatile byproducts were distilled out of the flask and collected. Distillation completed in four hours. Heating stopped immediately after distillation is finished. Totally 96 grams of distillate were collected. Fresh propylene glycol methyl ether acetate of 164 grams was immediately added to the flask to reduce temperature. Final content of the flask was used, as Resin I, for compositions of the negative-tone photo-imageable hardmask without further processing.

### Example 2

### Synthesis of Polysiloxane and Polysilsesquioxane Resin II

TABLE 2
Monomers for Polysiloxane and Polysilsesquioxane Resin II:

| | |
|---|---|
| Methyl trimethoxy silane (Gelest, Morrisville, PA) | 67.8 grams |
| Tetraethoxy silane (Gelest, Morrisville, PA) | 26.6 grams |
| 2-(3,4-Epoxycyclohexyl)ethyl trimethoxy silane | 3.14 grams |
| (Gelest, Morrisville, PA) | |

Monomers in Table 2, together with 80 grams of propylene glycol methyl ether acetate (from Aldrich, Milwaukee, Wis.), were mixed in a 500-mL three-neck round-bottom flask. Attached to the flak were distillation condenser, thermometer, and nitrogen inlet. Nitrogen flow was set at 200 milliliters per minute. With stirring, temperature of the mixture in the flask was raised to 95° C. in oil bath. Then, 50 grams of 3-normal acetic acid were slowly added to the flask. Condensation reactions began. Volatile byproducts were distilled out of the flask and collected. Distillation completed in four hours. Heating stopped immediately after distillation is finished. Totally 94.4 grams of distillate were collected. Fresh propylene glycol methyl ether acetate of 154 grams was immediately added to the flask to reduce temperature. Final content of the flask was used, as Resin II, for compositions of the negative-tone photo-imageable hardmask without further processing.

### Example 3

### Negative-Tone Photo-Imageable Hardmask Composition I

TABLE 3
Ingredients of Negative-tone Photo-
imageable Hardmask Composition I

| | |
|---|---|
| Resin I (from Example 1) | 38 g |
| Diphenylsilanediol (Gelest, Morrisville, PA) | 0.2 g |
| Triphenylsulfonium tris(trifluoromethyl)methide | 0.04 g |
| (Ciba,Basel, Switzerland) | |
| Benzyltriethylammonium chloride | 0.01 g |
| (Aldrich, Milwaukee, WI) | |
| Propylene glycol methyl ether acetate | 100 g |

Composition I was made by mixing the ingredients in Table 3. When all the solids dissolved, the composition was filtered through a membrane with 0.02-micrometer pores. In the composition, film-modifier, that is diphenylsilanediol, is 5% of the resin by weight. Molar ratio of photoacid generator, that is triphenylsulfonium tris(trifluoromethyl)methide, to quencher, that is benzyltriethylammonium chloride, is 4 to 3. Photoacid generator load is 0.029% of total composition weight.

Lithographic Conditions for Composition I:

| | |
|---|---|
| Wafer spin speed for coating | 1500-3000 revolutions per minute for film |
| | thickness of 40-60 nm |
| Post application bake | 40-100° C. for 60 sec |
| Suitable radiation | 193 nanometers, 248 nanometers, 13.5 |
| wavelengths | nanometers, and 365 nanometers |
| Post exposure bake | 60-100° C. for 90 sec |
| Development | 10 seconds to 40 seconds in 4.8 grams of |
| | tetramethylammonium hydroxide per liter |
| | aqueous solution by spray, puddling or |
| | submerge |

Film of Composition I after post-exposure bake is consisted of 36% or more silicon by weight.

### Example 4

### Negative-Tone Photo-Imageable Hardmask Composition II

TABLE 4
Ingredients of Negative-tone Photo-
imageable Hardmask Composition II

| | |
|---|---|
| Resin II (from Example 2) | 38 g |
| Diphenylsilanediol (Gelest, Morrisville, PA) | 0.2 g |
| Triphenylsulfonium tris(trifluoromethyl)methide | 0.04 g |
| (Ciba, Basel, Switzerland) | |
| Benzyltriethylammonium chloride | 0.01 g |
| (Aldrich, Milwaukee, WI) | |
| Propylene glycol methyl ether acetate | 100 g |

Composition II was made by mixing the ingredients in Table 4. When all the solids dissolved, the composition was filtered through a membrane with 0.02-micrometer pores. In the composition, film-modifier, that is diphenylsilanediol, is 5% of the resin by weight. Molar ratio of photoacid generator, that is triphenylsulfonium tris(trifluoromethyl)methide, to quencher, that is benzyltriethylammonium chloride, is 4 to 3. Photoacid generator load is 0.029% of total composition weight.

Lithographic Conditions for Composition II:

| | |
|---|---|
| Wafer spin speed for coating | 1500-3000 revolutions per minute for film |
| | thickness of 40-60 nm |
| Post application bake | 40-100° C. for 60 sec |
| Suitable radiation | 193 nanometers, 248 nanometers, 13.5 |
| wavelengths | nanometers, and 365 nanometers |
| Post exposure bake | 60-100° C. for 90 sec |
| Development | 10 seconds to 40 seconds in 4.8 grams of |
| | tetramethylammonium hydroxide per liter |
| | aqueous solution by spray, puddling or |
| | submerge |

Film of Composition II after post-exposure bake is consisted of 38% or more silicon by weight.

### Example 5

### Negative-Tone Photo-Imageable Hardmask Composition III

TABLE 5
Ingredients of Negative-tone Photo-
imageable Hardmask Composition III

| | |
|---|---|
| Resin I (from Example 1) | 39 g |
| 1,1,1-Tris(hydroxymethyl)ethane (Aldrich, Milwaukee, WI) | 0.1 g |
| Triphenylsulfonium tris(trifluoromethyl)methide | 0.04 g |
| (Ciba, Basel, Switzerland) | |
| Benzyltriethylammonium chloride | 0.01 g |
| (Aldrich, Milwaukee, WI) | |
| Propylene glycol methyl ether acetate | 100 g |

Composition III was made by mixing the ingredients in Table 5. When all the solids dissolved, the composition was filtered through a membrane with 0.02-micrometer pores. In the composition, film-modifier, that is 1,1,1-tris(hydroxymethyl)ethane), is 2.5% of the resin by weight. Molar ratio of photoacid generator, that is triphenylsulfonium tris(trifluoromethyl)methide, to quencher, that is benzyltriethylammonium chloride, is 4 to 3. Photoacid generator load is 0.029% of total composition weight.

Lithographic Conditions for Composition III:

| | |
|---|---|
| Wafer spin speed for coating | 1500-3000 revolutions per minute for film |
| | thickness of 40-60 nm |
| Post application bake | 40-100° C. for 60 sec |
| Suitable radiation | 193 nanometers, 248 nanometers, 13.5 |
| wavelengths | nanometers, and 365 nanometers |
| Post exposure bake | 60-100° C. for 90 sec |
| Development | 10 seconds to 40 seconds in 4.8 grams of |
| | tetramethylammonium hydroxide per liter |
| | aqueous solution by spray, puddling or |
| | submerge |

Film of Composition III after post-exposure bake is consisted of 36% or more silicon by weight.

### Example 6

### Negative-Tone Photo-Imageable Hardmask Composition IV

TABLE 6
Ingredients of Negative-tone Photo-
imageable Hardmask Composition IV

| | |
|---|---|
| Resin II (from Example 2) | 39 g |
| 1,1,1-Tris(hydroxymethyl)ethane (Aldrich, Milwaukee, WI) | 0.1 g |
| Triphenylsulfonium tris(trifluoromethyl)methide | 0.04 g |
| (Ciba, Basel, Switzerland) | |
| Benzyltriethylammonium chloride | 0.01 g |
| (Aldrich, Milwaukee, WI) | |
| Propylene glycol methyl ether acetate | 100 g |

Composition IV was made by mixing the ingredients in Table 6. When all the solids dissolved, the composition was filtered through a membrane with 0.02-micrometer pores. In the composition, film-modifier, that is 1,1,1-tris(hydroxymethyl)ethane), is 2.5% of the resin by weight. Molar ratio of photoacid generator, that is triphenylsulfonium tris(trifluoromethyl)methide, to quencher, that is benzyltriethylammonium chloride, is 4 to 3. Photoacid generator load is 0.029% of total composition weight.

Lithographic Conditions for Composition IV

| | |
|---|---|
| Wafer spin speed for coating | 1500-3000 revolutions per minute for film |
| | thickness of 40-60 nm |
| Post application bake | 40-100° C. for 60 sec |
| Suitable radiation | 193 nanometers, 248 nanometers, 13.5 |
| wavelengths | nanometers, and 365 nanometers |
| Post exposure bake | 60-100° C. for 90 sec |
| Development | 10 seconds to 40 seconds in 4.8 grams of |
| | tetramethylammonium hydroxide per liter |
| | aqueous solution by spray, puddling or |
| | submerge |

Film of Composition IV after post-exposure bake is consisted of 38% or more silicon by weight.

### Example 7

### Negative-Tone Photo-Imageable Hardmask Composition V

TABLE 7
Ingredients of Negative-tone Photo-
imageable Hardmask Composition V

| | |
|---|---|
| Resin I (from Example 1) | 39 g |
| 1,1,1-Tris(hydroxymethyl)ethane (Aldrich, Milwaukee, WI) | 0.1 g |
| Triphenylsulfonium tris(trifluoromethyl)methide | 0.04 g |
| (Ciba, Basel, Switzerland) | |
| Triethanolamine (Aldrich, Milwaukee, WI) | 0.0066 g |
| Propylene glycol methyl ether acetate | 100 g |

Composition V was made by mixing the ingredients in Table 7. When all the solids dissolved, the composition was filtered through a membrane with 0.02-micrometer pores. In the composition, film-modifier, that is 1,1,1-tris(hydroxymethyl)ethane), is 2.5% of the resin by weight. Molar ratio of photoacid generator, that is triphenylsulfonium tris(trifluoromethyl)methide, to quencher, that is triethanolamine, is 4 to 3. Photoacid generator load is 0.029% of total composition weight.

Lithographic Conditions for Composition V:

| | |
|---|---|
| Wafer spin speed for coating | 1500-3000 revolutions per minute for film |
| | thickness of 40-60 nm |
| Post application bake | 40-100° C. for 60 sec |
| Suitable radiation | 193 nanometers, 248 nanometers, 13.5 |
| wavelengths | nanometers, and 365 nanometers |
| Post exposure bake | 60-100° C. for 90 sec |
| Development | 10 seconds to 40 seconds in 4.8 grams of |
| | tetramethylammonium hydroxide per liter |
| | aqueous solution by spray, puddling or |
| | submerge |

Film of Composition V after post-exposure bake is consisted of 36% or more silicon by weight.

### Example 8

### Negative-Tone Photo-Imageable Hardmask Composition VI

TABLE 7
Ingredients of Negative-tone Photo-
imageable Hardmask Composition VI

| | |
|---|---|
| Resin I (from Example 1) | 39 g |
| 1,1,1-Tris(hydroxymethyl)ethane (Aldrich, Milwaukee, WI) | 0.1 g |
| Triphenylsulfonium triflate (Aldrich, Milwaukee, WI) | 0.025 g |
| Benzyltriethylammonium chloride | 0.0096 g |
| (Aldrich, Milwaukee, WI) | |
| Propylene glycol methyl ether acetate | 100 g |

Composition VI was made by mixing the ingredients in Table 7. When all the solids dissolved, the composition was filtered through a membrane with 0.02-micrometer pores. In the composition, film-modifier, that is 1,1,1-tris(hydroxymethyl)ethane), is 2.5% of the resin by weight. Molar ratio of photoacid generator, that is triphenylsulfonium triflate, to quencher, that is benzyltriethylammonium chloride, is 100 to 70. Photoacid generator load is 0.018% of total composition weight.

Lithographic Conditions for Composition VI:

| | |
|---|---|
| Wafer spin speed for coating | 1500-3000 revolutions per minute for film |
| | thickness of 40-60 nm |
| Post application bake | 40-100° C. for 60 sec |
| Suitable radiation | 193 nanometers, 248 nanometers, 13.5 |
| wavelengths | nanometers, and 365 nanometers |
| Post exposure bake | 60-100° C. for 90 sec |
| Development | 10 seconds to 40 seconds in 4.8 grams of |
| | tetramethylammonium hydroxide per liter |
| | aqueous solution by spray, puddling or |
| | submerge |

Film of Composition VI after post-exposure bake is consisted of 36% or more silicon by weight.

What is claimed is:

1. A method of making silicon hardmask films photo-imageable with a negative tone, said method comprising incorporation of a photoacid generator and film modifier in compositions, said photoacid generator being a chemical compound capable of producing acid upon exposure to radiations, said acid capable of catalyzing condensation reactions of said silicon hardmask films, and said radiations having wavelengths shorter than 400 nanometers.

2. The method of claim 1, wherein said condensation reactions taking place in said silicon hardmask films at post-exposure-bake temperatures between 60° C. and 120° C., and said condensation reactions forming molecular networks.

3. The method of claim 1, wherein unradiated hardmask films not forming molecular networks due to lack of photo-generated catalyst, and lack of molecular networks leaving said hardmask films soluble or dispersible in organic solvents or alkaline aqueous solutions.

4. The method of claim 1, wherein radiated hardmask films forming molecular networks due to catalyzation of photo-generated acid, said molecular networks preventing said hardmask films from dissolving or dispersing in organic solvents or alkaline aqueous solutions.

5. The method of claim 1, wherein said film modifier is based on concept of constraining diffusion pathways of said photoacid generator, and said film modifier filing film pores of said silicon hardmask, and film-modifier molecules bonding to film molecules, and said bonding taking place at post-exposure-bake temperatures.

6. Compositions of photo-imageable hardmask with negative tone, said compositions comprising of:
polymeric resin, said resin is prepared from monomers with molecular structures of 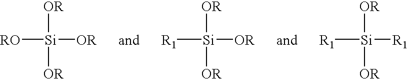
wherein R is selected from groups consisting of hydrogen and C₁-C₄ alkyls, and R₁ is selected from groups consisting of alkyl, aryl, alkene, alicyclic, epoxy-alkyl, and epoxy-cycloalkyl, and polymerization taking place to said monomers with presence of catalysts in organic solvents under temperatures from 80° C. to 110° C., and volatile alkanols being formed and removed, and polysiloxanes and polysilsesquioxanes being formed with molecular structures of 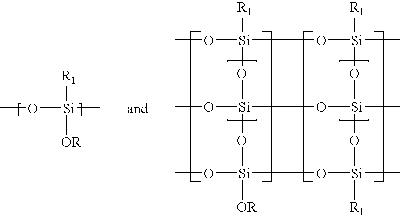
wherein R is selected from groups consisting of hydrogen and C₁-C₄ alkyls, and R₁ is selected from groups consisting of alkyl, aryl, alkene, alicyclic groups, epoxy-alkyl, and epoxy-cycloalkyl, and
a photoacid generator, said photoacid generator is selected from known photoacid generators, said known photoacid generators including
onium salts, said onium salts including triphenylsulfonium tris(trifluoromethyl)methide, and molar ratio of said photoacid generator to said catalyst being 0.5 to 1.5, and
a film-modifier, said film-modifier is selected from polymers, oligomers, or non-polymeric compounds, and molecules of said film-modifier small enough to fill in film pores, and said film-modifier having at least one hydroxyl functional group on each molecule, and said film-modifiers including polyols, said polyols including 1,1,1-tris(hydroxymethyl)ethane and pentaerythritol, and said film-modifiers including silicon-containing compounds, said silicon-containing compounds including silanols, said silanols including diphenylsilanediol, and
a quencher, said quencher is selected from alkaline compounds, said alkaline compounds capable of neutralizing photo-generated acid, and said alkaline compounds including n-boc-piperidine, t-butyl 4-hydroxy-1-piperidinecarboxylate, triethanol amine, 1-piperidineethanol, and benzyltriethylammonium chloride, and molar ratio of said quencher to said photoacid generator is 0.2-10, and
a solvent or mixture of solvents, said solvents including propylene glycol methyl ether, propylene glycol methyl ether acetate and ethyl lactate.

7. The compositions of claim 6, wherein said polymer resin and other solid chemicals making up less than ten percent of total composition weight.

8. The compositions of claim 6, wherein said photo-imageable hardmask consisting of 30%-41% silicon in dry films.

9. A process of forming precursor structures on semiconductor substrates using negative-tone photo-imageable hardmask in conjunction with an intermediate layer, said process comprising of:
forming an intermediate layer on a semiconductor substrate by spin-coating a composition, said composition comprising of at least a hydrocarbon resin and a solvent, and said semiconductor substrate including polysilicon, dielectrics and metals, and said semiconductor substrate having a flat surface or structured surface, and
curing said intermediate layer on a hot surface, and cured intermediate layer having a thickness from 100 nanometers to 500 nanometers, and
forming a film of negative-tone photo-imageable hardmask on said intermediate layer by spin-coating a composition of claim 6, and
drying film said of negative-tone photo-imageable hardmask on a hotplate surface, said hotplate surface having a temperature between 40° C. and 100° C., and dried film of negative-tone photo-imageable hardmask having a thickness between 20 nanometers and 100 nanometers, and
exposing said film of negative-tone photo-imageable hardmask to a radiation with image contrast, said radiation having a wavelength shorter than 400 nanometers, and
conditioning exposed film of photo-imageable hardmask on a heated surface, said heated surface having a temperature between 60° C. and 100° C., and
removing unradiated portions from said image contrast of said film of negative-tone photo-imageable hardmask by organic solvents or alkaline aqueous solutions, said alkaline aqueous solutions including tetramethylammonium hydroxide water solutions, and said removing method including submerge and spray, and said removing process yielding images on said film of negative-tone photo-imageable hardmask, and
removing portions of said intermediate layer under open areas of said images on said negative-tone photo-imageable hardmask by plasma, said plasma comprising of gases including oxygen, and said removing process yielding images on said intermediate layer, and
removing portions of said substrate under open areas of said images on said intermediate layer by plasma, said plasma comprising of gases including chlorine, hydrogen bromide and fluorinated hydrocarbons, and said removing process yielding structures on said substrate, and
removing residual intermediate layer from said substrate.

10. The process of claim 9, wherein said intermediate layer may be replaced by a thin antireflective coating.

11. The process of claim 10, wherein said process with a thin antireflective coating comprising of:
forming a thin antireflective coating on a semiconductor substrate by spin-coating a composition, said semiconductor substrate including polysilicon, dielectrics and metals, and said semiconductor substrate having a flat surface or structured surface, and
curing said thin antireflective coating on a heated surface, and cured thin antireflective coating having a thickness from 20 nanometers to 80 nanometers, and
forming a film of negative-tone photo-imageable hardmask on said antireflective coating by spin-applying a composition of claim 6, and
drying film of said negative-tone photo-imageable hardmask on a heated surface, said heated surface having a temperature between 40° C. and 100° C., and dried film of negative-tone photo-imageable hardmask having a thickness between 20 nanometers and 100 nanometers, and
exposing said film of negative-tone photo-imageable hardmask to a radiation with image contrast, said radiation having a wavelength shorter than 400 nanometers, and
conditioning exposed film of negative-tone photo-imageable hardmask on a heated surface, said heated surface having a temperature between 60° C. and 100° C., and
removing unradiated portions from said image contrast of said film of negative-tone photo-imageable hardmask by organic solvents or alkaline aqueous solutions, said alkaline aqueous solutions including tetramethylammonium hydroxide water solutions, and said removing method including submerge and spray, and said removing process yielding images on said film of negative-tone photo-imageable hardmask, and
removing portions of said antireflective coating and said substrate under open areas of said images on said negative-tone photo-imageable hardmask by plasma, said plasma comprising of gases including oxygen, chlorine, hydrogen bromide and fluorinated hydrocarbons, and said removing process yielding structures on said substrate, and
removing residual negative-tone photo-imageable hardmask and antireflective coating from said substrate.
